(19) United States
(12) Patent Application Publication
(10) Pub. No.: US 2026/0213130 A1
(43) Pub. Date: Jul. 23, 2026

(54) ELECTRICAL VARIABLE CAPACITOR BASED IMPEDANCE MATCHING CIRCUIT AND SYSTEM FOR MANUFACTURING SEMICONDUCTOR USING THE SAME

(71) Applicant: INDUSTRIAL COOPERATION FOUNDATION JEONBUK NATIONAL UNIVERSITY, Jeonju-si (KR)

(72) Inventors: Yong sug Suh, Jeonju-si (KR); Hee won Choi, Jeonju-si (KR)

(73) Assignee: INDUSTRIAL COOPERATION FOUNDATION JEONBUK NATIONAL UNIVERSITY, Jeonju-si (KR)

(21) Appl. No.: 18/717,339

(22) PCT Filed: Jan. 31, 2024
(86) PCT No.: PCT/KR2024/001449

§ 371 Date: Jun. 6, 2024

(30) Foreign Application Priority Data
Apr. 7, 2023 (KR) 10-2023-0046073
Jul. 10, 2023 (KR) 10-2023-0088841

(51) Int. Cl. H01J 37/32; H03H 11/28; H10P 72/00

(52) U.S. Cl. CPC H01J 37/32183; H03H 11/28; H01J 2237/334; H10P 72/0421

(57) ABSTRACT

The disclosure relates to an electrical variable capacitor-based impedance matching circuit and a semiconductor manufacturing system using the same. The system includes an RF power supply generating and supplying RF power; a plasma chamber receiving RF power from the RF power supply; and an impedance matching circuit placed between the RF power supply and the plasma chamber to match impedance of the RF power supply and the plasma chamber. The impedance matching circuit includes a plurality of electrical variable capacitor circuits. Each of the electrical variable capacitor circuits includes a first node connected to one side of the RF power supply; a second node connected to another side of the RF power supply; a capacitor connected to the first node; an inductor connected in series with the capacitor; and a switch connected in parallel with the inductor.

### TECHNICAL FIELD

The following description relates to an electrical variable capacitor-based impedance matching circuit and a semiconductor manufacturing system using the same.

### BACKGROUND ART

Recently, there has been increasing interest in semiconductor manufacturing processes. Specifically, there is growing interest in the etching and deposition process using Radio Frequency (RF) plasma processes among semiconductor manufacturing processes. Semiconductor process systems for performing RF plasma processes typically consist of an RF power supply, a plasma chamber, and an impedance matching circuit.

The impedance matching circuit may match the impedance between the RF power supply and the plasma chamber so that the maximum power is always transmitted to the plasma chamber. The load of the plasma chamber may vary constantly depending on the type and amount of gas used and whether or not plasma is generated. To transmit maximum power to the plasma chamber regardless of the load variation in the plasma chamber, an impedance matching circuit is essentially required for the semiconductor manufacturing system.

Conventional impedance matching circuits include a capacitor (e.g., a vacuum variable capacitor) that mechanically varies its capacitance its capacitance to match the impedance in response to the varying load in the plasma chamber. However, vacuum variable capacitors have an issue with their slow response time (e.g., approximately 30% in the etching process) due to mechanical variations in capacitance.

Therefore, there is increasing interest and research in impedance matching circuits using an electrical variable capacitor that changes electrically change the capacitor. However, known electrical variable capacitors have a large number of active elements and require an external power source, resulting in a rather large volume. Therefore, there arises a necessity for an impedance matching circuit based on an electrical variable capacitor that may reduce the number of active elements and reduce the volume without relying on an external power source.

### DISCLOSURE

### Technical Problem

An object of the present invention is to provide an electrical variable capacitor-based impedance matching circuit and a semiconductor manufacturing system using the same that may reduce the number of active elements to solve the aforementioned problems, thereby saving costs and reducing volume.

### Solution to Problem

In order to achieve this purpose, in one general aspect, a semiconductor manufacturing system includes an RF power supply generating and supplying RF power; a plasma chamber receiving RF power from the RF power supply; and an impedance matching circuit placed between the RF power supply and the plasma chamber to match impedance of the RF power supply and the plasma chamber. The impedance matching circuit includes a plurality of electrical variable capacitor circuits. Each of the electrical variable capacitor circuits includes a first node connected to one side of the RF power supply; a second node connected to another side of the RF power supply; a capacitor connected to the first node; an inductor connected in series with the capacitor; and a switch connected in parallel with the inductor.

The switch may be a power semiconductor switch without a body diode.

The semiconductor manufacturing system may further include a control unit for controlling switching operations of the switch.

The semiconductor manufacturing system may further include an external power source supplying low-voltage power to each of the electrical variable capacitor circuits.

In one general aspect, an electrical variable capacitor-based impedance matching circuit includes a plurality of electrical variable capacitor circuits. Each of the electrical variable capacitor circuits includes a first node connected to one side of the RF power supply; a second node connected to another side of the RF power supply; a capacitor connected to the first node; an inductor connected in series with the capacitor; and a switch connected in parallel with the inductor.

The switch may be a power semiconductor switch without a body diode.

The impedance matching circuit may further include an external power source supplying low-voltage power to each of the electrical variable capacitor circuits.

In another general aspect, a semiconductor manufacturing system includes an RF power supply generating and supplying RF power; a plasma chamber receiving RF power from the RF power supply; and an impedance matching circuit placed between the RF power supply and the plasma chamber to match impedance of the RF power supply and the plasma chamber. The impedance matching circuit includes a plurality of electrical variable capacitor circuits. Each of the electrical variable capacitor circuits includes a first node connected to one side of the RF power supply; a second node connected to another side of the RF power supply; a capacitor connected to the first node; an inductor connected in series with the capacitor; a diode connected in series with the inductor; and a switch connected in parallel with the diode and the inductor.

The switch may be a power semiconductor switch with a body diode.

The semiconductor manufacturing system may further include an external power source supplying low-voltage power to each of the electrical variable capacitor circuits.

In another general aspect, an electrical variable capacitor-based impedance matching circuit includes a plurality of electrical variable capacitor circuits. Each of the electrical variable capacitor circuits includes a first node connected to one side of an RF power supply; a second node connected to another side of the RF power supply; a capacitor connected to the first node; an inductor connected in series with the capacitor; a diode connected in series with the inductor; and a switch connected in parallel with the diode and the inductor.

The switch may include a power semiconductor switch with a body diode.

The impedance matching circuit may further include an external power source supplying low-voltage power to each of the electrical variable capacitor circuits.

In another general aspect, a semiconductor manufacturing system includes an RF power supply generating and supplying RF power; a plasma chamber receiving RF power from the RF power supply; and an impedance matching circuit placed between the RF power supply and the plasma chamber to match impedance of the RF power supply and the plasma chamber. The impedance matching circuit includes a plurality of electrical variable capacitor circuits. Each of the electrical variable capacitor circuits includes: a first node connected to one side of the RF power supply; a second node connected to another side of the RF power supply; a capacitor connected to the first node; an inductor connected in series with the capacitor; a first switch connected in parallel with the inductor; and a second switch connected in series with the inductor.

The first switch and the second switch may be power semiconductor switches with a body diode.

The semiconductor manufacturing system may further include an external power source supplying low-voltage power to each of the electrical variable capacitor circuits.

In another general aspect, an electrical variable capacitor-based impedance matching circuit includes a plurality of electrical variable capacitor circuits. Each of the electrical variable capacitor circuits includes a first node connected to one side of an RF power supply; a second node connected to another side of the RF power supply; a capacitor connected to the first node; an inductor connected in series with the capacitor; a first switch connected in parallel with the inductor; and a second switch connected in series with the inductor.

The first switch and the second switch may be power semiconductor switches with a body diode.

The impedance matching circuit may further include an external power source supplying low-voltage power to each of the electrical variable capacitor circuits.

### Effects of Invention

An electrical variable capacitor-based impedance matching circuit and a semiconductor manufacturing system using the same in accordance with an embodiment of the present disclosure can reduce the number of elements (e.g., active elements) (some embodiments do not even require an external power source), which can reduce the volume of the overall circuit, and can be cost competitive. In addition, according to the present invention, the entire circuit can be simplified, allowing for simple control.

### BRIEF DESCRIPTION OF DRAWINGS

FIG. 1 illustrates a schematic diagram showing a semiconductor manufacturing system according to one embodiment of the present disclosure.

FIG. 2 illustrates a detailed diagram showing the configuration of an electrical variable capacitor-based impedance matching circuit according to an embodiment of the present disclosure.

FIG. 3 illustrates a detailed diagram showing the configuration of an electrical variable capacitor-based impedance matching circuit according to another embodiment of the present disclosure.

FIG. 4 illustrates a detailed diagram showing the configuration of an electrical variable capacitor-based impedance matching circuit according to another embodiment of the present disclosure.

FIG. 5 illustrates a detailed diagram showing the configuration of an electrical variable capacitor-based impedance matching circuit according to another embodiment of the present disclosure.

FIG. 6 illustrates a diagram showing the impedance matching state when using an electrical variable capacitor-based impedance matching circuit according to an embodiment of the present disclosure.

FIG. 7 illustrates a diagram showing the impedance matching state when using an electrical variable capacitor-based impedance matching circuit according to another embodiment of the present disclosure.

FIG. 8 illustrates a diagram showing the impedance matching state when using an electrical variable capacitor-based impedance matching circuit according to another embodiment of the present disclosure.

### BEST MODE FOR IMPLEMENTATION OF THE INVENTION

Hereinafter, preferred embodiments of the present invention will be described in detail with reference to the accompanying drawings. Advantages and features of the present invention and a method of achieving them will become apparent with reference to the embodiments described below in detail with the accompanying drawings. However, the present invention is not limited to the embodiments disclosed below, but will be implemented in various different forms, and only the present embodiments are provided to ensure that the disclosure of the present invention is complete, to fully inform those of ordinary skill in the art to which the present invention belongs, and the present invention is only defined by the scope of the claims. Hereinafter, the same reference numerals refer to the same elements.

Although first, second, etc. are used to describe various devices, components, and/or sections, these devices, components, and/or sections are not limited by these terms. These terms are used only to distinguish one device, component, or section from other devices, components, or sections. Therefore, it goes without saying that the first element, the first element, the first element, or the first section mentioned below may be a second element, a second element, or a second section within the technical idea of the present invention.

The terms used herein are intended to describe embodiments and are not intended to limit the present invention. In the present specification, a singular form also includes a plural form unless specifically stated in the text. As used in the specification, “comprises” and/or “made of” do not preclude the presence or addition of one or more other components, steps, operations and/or elements mentioned.

Unless otherwise defined, all terms (including technical and scientific terms) used in the present specification may be used in a meaning commonly understood by those skilled in the art to which the present invention pertains. In addition, terms defined in commonly used dictionaries are not ideally or excessively interpreted unless clearly and specifically defined.

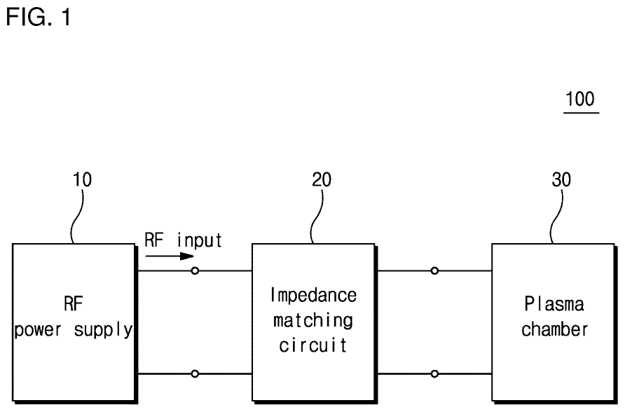

FIG. 1 illustrates a schematic diagram showing a semiconductor manufacturing system according to one embodiment of the present disclosure.

Referring to FIG. 1, a semiconductor manufacturing system according to one embodiment of the present disclosure may include a Radio Frequency (RF) power supply 10, an impedance matching circuit 20, and a plasma chamber 30.

The RF power supply 10 may generate and supply RF power. For example, the RF power supply 10 may generate power (e.g., RF power) for generating plasma within the plasma chamber 30 and power for controlling ion energy in the plasma, and may provide (apply) the generated power to the plasma chamber 30. The power (e.g., voltage pulses) may have a frequency of several kHz to tens of MHz, and may have a voltage level of tens of V to tens of kV. The voltage pulses may include a positive section with a constant voltage level as a source power for generating plasma and a negative section with a variable voltage level as bias power for controlling the ion energy of the plasma.

The RF power supply 10 according to an embodiment may include a pulse generator circuit for generating a square wave and a slope adjustment circuit for adjusting a slope of a negative section of the generated square wave.

The impedance matching circuit 20 may be placed between the RF power supply 10 and the plasma chamber 30 to match the impedances of the RF power supply and the plasma chamber 30. For example, the impedance matching circuit 20 can match the impedance of the RF power outputted from the RF power supply 10 (e.g., 50 ohms) with the irregularly varying impedance of the plasma chamber 30. This allows the impedance matching circuit 20 to ensure that the output of the RF power supply 10 is transmitted to the plasma chamber 30 with as little loss as possible.

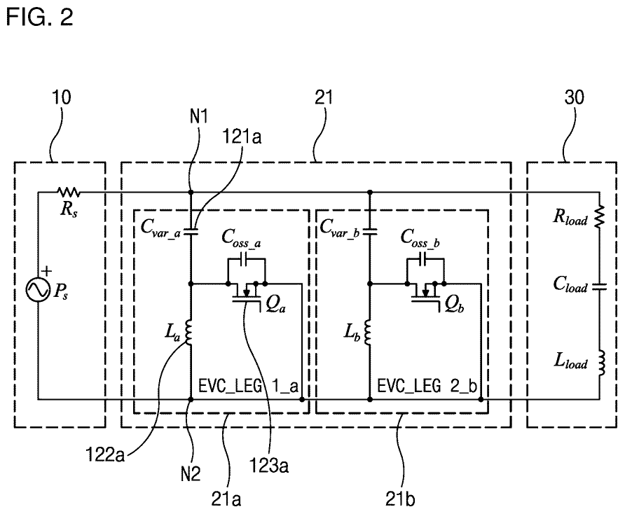

The impedance matching circuit 20 according to an embodiment may include an electrical variable capacitor (EVC) circuit for fast matching speed. The electrical variable capacitor may have a matching speed about 1000 times faster than that of a vacuum variable capacitor. Furthermore, an electrical variable capacitor circuit according to one or more embodiments of the present disclosure does not require an external power source and requires fewer elements (e.g., active elements), compared to conventionally known electrical variable capacitor circuits. As a result, the electrical variable capacitor-based impedance matching circuit according to embodiments of the present disclosure and a semiconductor manufacturing system including the same may maintain fast matching speed and reduce the volume and manufacturing costs (unit price). Hereinafter, a detailed description of the electrical variable capacitor circuit will be described with reference to FIGS. 2, 3, and 4.

The plasma chamber 30 may receive RF power from the RF power supply 10. When RF power generated by the RF power supply 10 (e.g., voltage pulses) is applied, the plasma chamber 30 may generate plasma. The generated plasma comes into contact with the surface of semiconductor components (e.g., a wafer) placed within the plasma chamber 30 and udergoes physical or chemical reactions. Through this reaction, treatment processes such as plasma annealing, etching, plasma enhancement, chemical vapor deposition, physical vapor deposition, and plasma cleaining, may be performed. For example, the plasma chamber 30 may etch a wafer through plasma generated by a positive (or negative) voltage pulse applied to a first electrode and a negative (or positive) voltage applied to a second electrode.

The plasma chamber 30 may act as a load. The impedance of the plasma chamber 30 may irregularly vary due to variables such as the type of gas, temperature, and pressure.

FIG. 2 illustrates a detailed diagram showing the configuration of an electrical variable capacitor-based impedance matching circuit according to an embodiment of the present disclosure.

Referring to FIG. 2, an electrical variable capacitor-based impedance matching circuit 21 according to an embodiment of the present disclosure may include a plurality of electrical variable capacitor circuits 21a, 21b. The plurality of electrical variable capacitor circuits 21a, 21b may have the same structure, each electrical variable capacitor circuit may include: a first node N1 connected to one side of the RF power supply 10, a second node N2 connected to another side of the RF power supply 10, a capacitor 121a connected to the first node N1, an inductor 122a connected in series with the capacitor 121a, and a switch 123a connected in parallel with the inductor 122a.

The capacitor 121a receives alternating current power (e.g., positive (+) power (current) from the RF power supply 10 through the first node N1. The inductor 122a receives alternating current power (e.g., negative (−) power (current)) from the RF power supply 10 through the second node N2. The switch 123a is switched (e.g., ON/OFF) based on a control signal, and may connect or disconnect the path between the connection point of the capacitor 121a and the inductor 122a and the second node N2. The switch 123a may be a power semiconductor switch that does not include a body diode. Meanwhile, the semiconductor manufacturing system 100 may further include a gate driver (not shown) to control the switching of the switch 123a and a control unit (e.g., processor) (not shown) to control the gate driver.

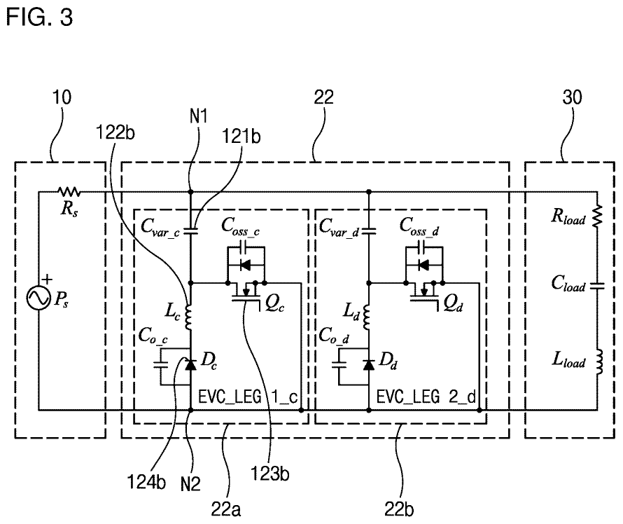

FIG. 3 illustrates a detailed diagram showing the configuration of an electrical variable capacitor-based impedance matching circuit according to another embodiment of the present disclosure.

Referring to FIG. 3, an electrical variable capacitor-based impedance matching circuit 22 according to another embodiment of the present disclosure may include a plurality of electrical variable capacitor circuits 22a, 22b. The plurality of electrical variable capacitor circuits 22a, 22b may have the same structure, and each electrical variable capacitor circuit may include a first node N1 connected to one side of an RF power supply 10, a second node N2 connected to another side of the RF power supply 10, a capacitor 121b connected to the first node N1, an inductor 122b connected in series with the capacitor 121b, a diode 124b connected in series with the inductor 122b, and a switch 123b connected in parallel with the diode 124b and the inductor 122b.

The electrical variable capacitor-based impedance matching circuit 22 may further include a diode 124b connected in series with the inductor 122b, and the switch 123b may be a power semiconductor switch including a body diode. The diode 124b serves to open the body diode component of the switch 123b, and the power semiconductor switch having a body diode generally has a higher breakdown voltage than a power semiconductor switch without a body diode, thereby facilitating use in high power systems. Even though the diode 124b is added, the electrical variable capacitor-based impedance matching circuit 22 has very little current flowing through the diode 124b, so there is also very little loss caused by the diode 124b.

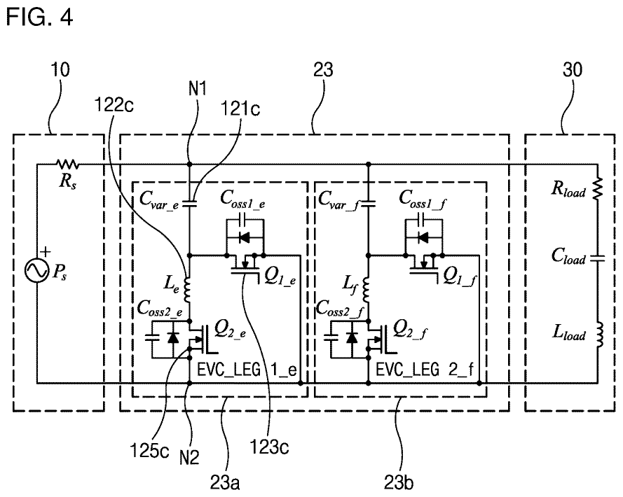

FIG. 4 illustrates a detailed diagram showing the configuration of an electrical variable capacitor-based impedance matching circuit according to another embodiment of the present disclosure.

Referring to FIG. 4, an electrical variable capacitor-based impedance matching circuit 23 according to another embodiment of the present disclosure may include a plurality of electrical variable capacitor circuits 23a, 23b. The plurality of electrical variable capacitor circuits 23a, 23b may have the same structure, and each electrical variable capacitor circuit may include a first node N1 connected to one side of the RF power supply 10, a second node N2 connected to another side of the RF power supply 10, a capacitor 121c connected to the first node N1, an inductor 122c connected in series with the capacitor 121c, a first switch 123c connected in parallel with the inductor 122c, and a second switch 125c connected in series with the inductor 122c. The first switch 123c and the second switch 125c may be power semiconductor switches including a body diode. In other words, the electrical variable capacitor-based impedance matching circuit 23 may include a second switch 125c instead of the diode 124b.

Meanwhile, FIGS. 2, 3, and 4 illustrate and describe the inclusion of two electrical variable capacitor circuits, but this is merely illustrative. They can be composed of three or more (e.g., 8 to 28) electrical variable capacitor circuits. Furthermore, the above explanations were provided with reference to their application in semiconductor fabrication. However, embodiments of the present disclosure may be applied to various systems, circuits, and/or devices requiring impedance matching. For instance, embodiments of the present disclosure may be applied as tuning capacitors in radio receivers with LC circuits.

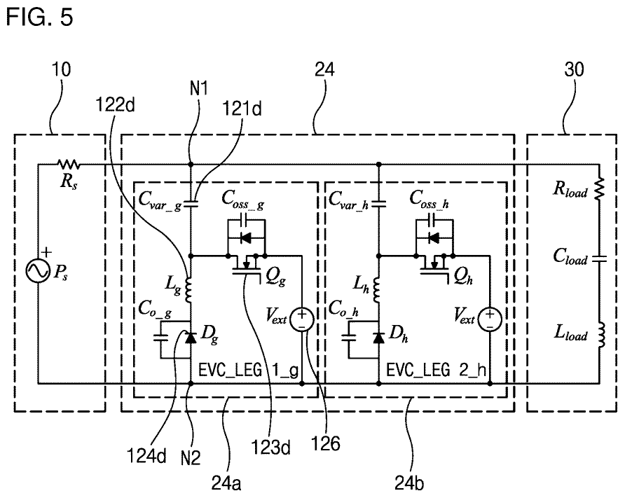

FIG. 5 illustrates a detailed diagram showing the configuration of an electrical variable capacitor-based impedance matching circuit according to another embodiment of the present disclosure.

Referring to FIG. 5, an electrical variable capacitor-based impedance matching circuit 23 according to another embodiment of the present disclosure may further include an external power source 126 for supplying low-voltage power to the electrical variable capacitor-based impedance matching circuit. As one embodiment, the external power source 126 may include a low-voltage power supply that compensates for the voltage drop caused by the forward voltage of the diode and switch.

The external power source 126 may be equally applicable to the embodiments of FIGS. 2 and 4. In other words, the present disclosure is not limited to not using the external power source 126 as in the embodiments of FIGS. 2 to 4, and may include the external power source 126 depending on the purpose of use of the circuit and changes in the devices used.

### Mode for Implementation of the Invention

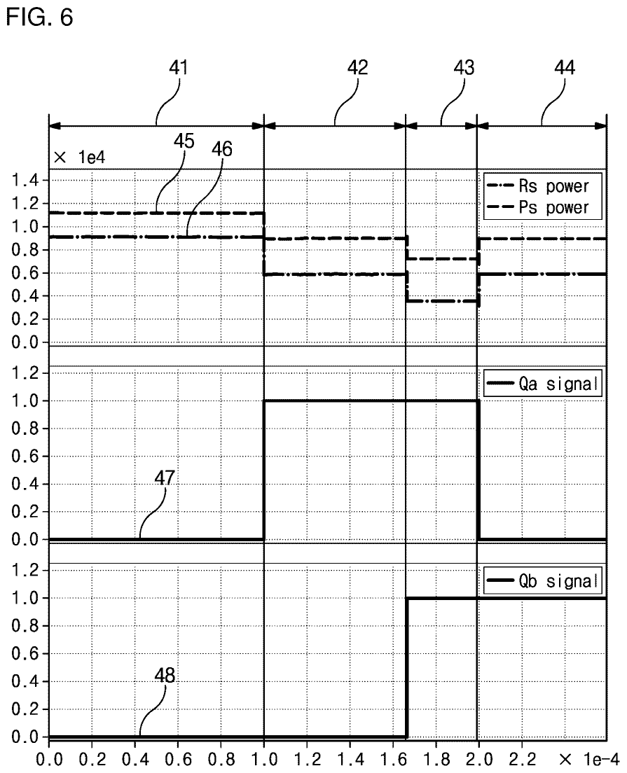

FIG. 6 illustrates a diagram showing the impedance matching state when using an electrical variable capacitor-based impedance matching circuit according to an embodiment of the present disclosure.

Referring to FIG. 6, the electrical variable capacitor-based impedance matching circuit 21 may be one of the following states: when both electrical variable capacitor circuits 21a, 21b are turned OFF (41); when one electrical variable capacitor circuit 21a is turned ON and the other electrical variable capacitor circuit 21b is turned OFF (42); when both electrical variable capacitor circuits 21a, 21b are turned ON (43); and when one electrical variable capacitor circuit 21a is turned OFF and the other electrical variable capacitor circuit 21b is turned OFF (44).

When half of a power 45 applied as input through the RF power supply 10 is applied to the load as power 46, it indicates impedance matching has occurred. As a result of checking the matching state, it can be confirmed that impedance matching has occurred when signals 47, 48 delivered to the two electrical variable capacitor circuits 21a, 21b are both ON signals (43). Through this, it can be seen that the electrical variable capacitor circuit according to an embodiment of the present disclosure may be used as an impedance matching circuit.

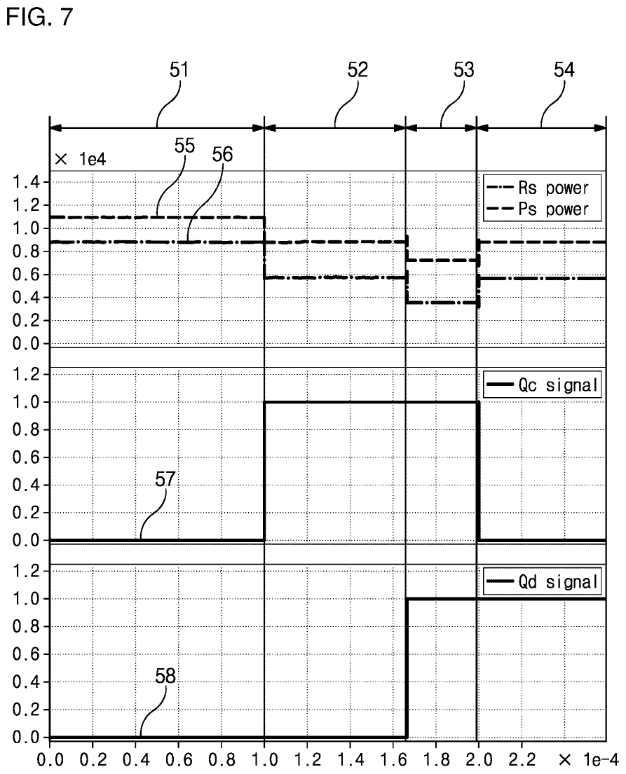

FIG. 7 illustrates a diagram showing the impedance matching state when using an electrical variable capacitor-based impedance matching circuit according to another embodiment of the present disclosure.

Referring to FIG. 7, an electrical variable capacitor-based impedance matching circuit 22 may be one of the following states: when both two electrical variable capacitor circuits 22a, 22b are turned OFF (51); when one electrical variable capacitor circuit 22a is turned ON and the other electrical variable capacitor circuit 22b is turned OFF (52); when both two electrical variable capacitor circuits 22a, 22b are turned ON (53); and when one electrical variable capacitor circuit 22a is turned OFF and the other electrical variable capacitor circuit 22b is turned ON (54).

When half of the power 55 applied as input through the RF power supply 10 is delivered to the load as power 65, it indicates impedance matching has occurred. As a result of checking the matching state, it can be confirmed that impedance matching has occurred when signals 57, 58 delivered to the electrical variable capacitor circuits 22a, 22b are both ON signals (53). Through this, it can be seen that the electrical variable capacitor circuit according to another embodiment of the present disclosure may be used as an impedance matching circuit.

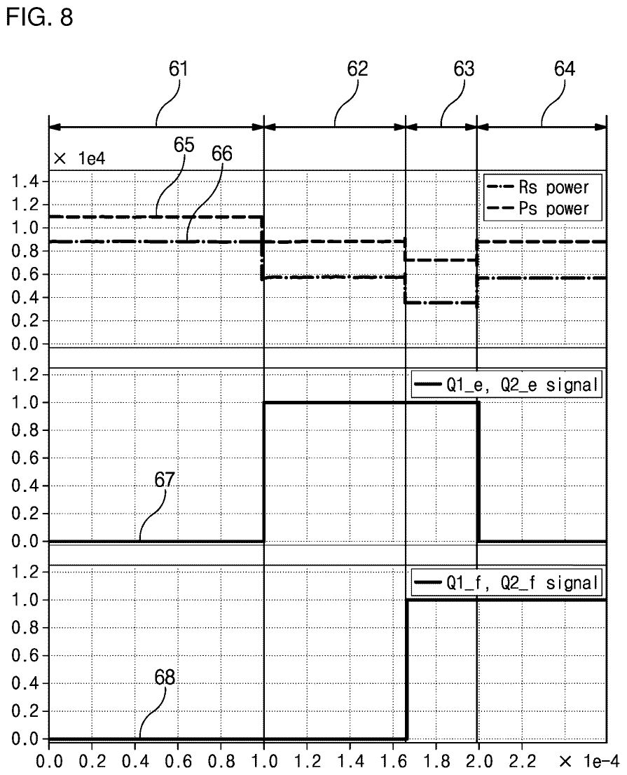

FIG. 8 illustrates a diagram showing the impedance matching state when using an electrical variable capacitor-based impedance matching circuit according to another embodiment of the present disclosure.

Referring to FIG. 8, the electrical variable capacitor-based impedance matching circuit 23 may be one of the following states: when both two electrical variable capacitor circuits 23a, 23b are turned OFF (61); when one electrical variable capacitor circuit 23a is turned ON and the other electrical variable capacitor circuit 23b is turned OFF (62); when both two electrical variable capacitor circuits 23a, 23b are turned ON (63); and when one electrical variable capacitor circuit 23a is turned OFF and the other electrical variable capacitor circuit 23b is turned OFF (64).

When half of the power 65 applied through the RF power supply 10 is applied to the load as power 66, it indicates impedance matching has occurred. As a result of checking the matching state, it can be confirmed that impedance matching has occurred when signals 67, 68 delivered to the two electrical variable capacitor circuits 23a, 23b are both ON signals (63). Through this, it can be seen that the electrical variable capacitor circuit according to another embodiment of the present disclosure may be used as an impedance matching circuit.

While the above has been described with reference to the illustrated embodiments of the invention, they are exemplary only, and it will be apparent to one having ordinary skill in the art to which the invention belongs that various modifications, changes, and equivalents are possible without departing from the spirit and scope of the invention. The true scope of technical protection of the invention should therefore be determined by the technical ideas of the appended claims.

### Industrial Applicability

This disclosure may be applied to impedance matching circuits, as well as semiconductor manufacturing systems including the same, etc.

What is claimed is:

1. A semiconductor manufacturing system, comprising:
an RF power supply generating and supplying RF power;
a plasma chamber receiving RF power from the RF power supply; and
an impedance matching circuit placed between the RF power supply and the plasma chamber to match impedance of the RF power supply and the plasma chamber,
wherein the impedance matching circuit comprises a plurality of electrical variable capacitor circuits, and
wherein each of the electrical variable capacitor circuits comprises:
a first node connected to one side of the RF power supply;
a second node connected to another side of the RF power supply;
a capacitor connected to the first node;
an inductor connected in series with the capacitor; and
a switch connected in parallel with the inductor.

2. The system of claim 1,
wherein the switch is a power semiconductor switch without a body diode.

3. The system of claim 1, further comprising:
a control unit for controlling switching operations of the switch.

4. The system of claim 1, further comprising:
an external power source supplying low-voltage power to each of the electrical variable capacitor circuits.

5. An impedance matching circuit,
the impedance matching circuit based on an electrical variable capacitor,
comprising a plurality of electrical variable capacitor circuits,
wherein each of the electrical variable capacitor circuits comprises:
a first node connected to one side of the RF power supply;
a second node connected to another side of the RF power supply;
a capacitor connected to the first node;
an inductor connected in series with the capacitor; and
a switch connected in parallel with the inductor.

6. The circuit of claim 5,
wherein the switch is a power semiconductor switch without a body diode.

7. The circuit of claim 5, further comprising:
an external power source supplying low-voltage power to each of the electrical variable capacitor circuits.

8. A semiconductor manufacturing system, comprising:
an RF power supply generating and supplying RF power;
a plasma chamber receiving RF power from the RF power supply; and
an impedance matching circuit placed between the RF power supply and the plasma chamber to match impedance of the RF power supply and the plasma chamber,
wherein the impedance matching circuit comprises a plurality of electrical variable capacitor circuits, and
wherein each of the electrical variable capacitor circuits comprises:
a first node connected to one side of the RF power supply;
a second node connected to another side of the RF power supply;
a capacitor connected to the first node;
an inductor connected in series with the capacitor;
a diode connected in series with the inductor; and
a switch connected in parallel with the diode and the inductor.

9. The system of claim 8,
wherein the switch is a power semiconductor switch with a body diode.

10. The system of claim 8, further comprising:
an external power source supplying low-voltage power to each of the electrical variable capacitor circuits.

11. An impedance matching circuit,
the impedance matching circuit based on an electrical variable capacitor,
comprising a plurality of electrical variable capacitor circuits,
wherein each of the electrical variable capacitor circuits comprises:
a first node connected to one side of an RF power supply;
a second node connected to another side of the RF power supply;
a capacitor connected to the first node;
an inductor connected in series with the capacitor;
a diode connected in series with the inductor; and
a switch connected in parallel with the diode and the inductor.

12. The circuit of claim 11,
wherein the switch comprises a power semiconductor switch with a body diode.

13. The circuit of claim 11, further comprising:
an external power source supplying low-voltage power to each of the electrical variable capacitor circuits.

14. A semiconductor manufacturing system, comprising:
an RF power supply generating and supplying RF power;
a plasma chamber receiving RF power from the RF power supply; and
an impedance matching circuit placed between the RF power supply and the plasma chamber to match impedance of the RF power supply and the plasma chamber,
wherein the impedance matching circuit comprises a plurality of electrical variable capacitor circuits, and
wherein each of the electrical variable capacitor circuits comprises:
a first node connected to one side of the RF power supply;
a second node connected to another side of the RF power supply;
a capacitor connected to the first node;
an inductor connected in series with the capacitor;
a first switch connected in parallel with the inductor; and
a second switch connected in series with the inductor.

15. The system of claim 14,
wherein the first switch and the second switch are power semiconductor switches with a body diode.

16. The system of claim 14, further comprising:
an external power source supplying low-voltage power to each of the electrical variable capacitor circuits.

17. An impedance matching circuit,
the impedance matching circuit based on an electrical variable capacitor,
comprising a plurality of electrical variable capacitor circuits,
wherein each of the electrical variable capacitor circuits comprises:
a first node connected to one side of an RF power supply;
a second node connected to another side of the RF power supply;
a capacitor connected to the first node;
an inductor connected in series with the capacitor;
a first switch connected in parallel with the inductor; and
a second switch connected in series with the inductor.

18. The circuit of claim 17,
wherein the first switch and the second switch are power semiconductor switches with a body diode.

19. The circuit of claim 17, further comprising:
an external power source supplying low-voltage power to each of the electrical variable capacitor circuits.
